(19) United States
(12) Patent Application Publication
(10) Pub. No.: US 2025/0183133 A1
(43) Pub. Date: Jun. 5, 2025

(54) SEMICONDUCTOR DEVICE PACKAGE WITH INTEGRATED LAMINATE TRANSFORMER

(71) Applicant: TEXAS INSTRUMENTS INCORPORATED, Dallas, TX (US)

(72) Inventors: Chun Ping Lo, Allen, TX (US); Enis Tuncer, Dallas, TX (US); Yi Yan, Dallas, TX (US)

(21) Appl. No.: 18/525,518

(22) Filed: Nov. 30, 2023

(51) Int. Cl. H01L 23/495; H01F 27/24; H01F 27/28; H01L 21/56; H01L 23/00; H01L 23/31

(52) U.S. Cl. CPC H01L 23/49575; H01F 27/24; H01F 27/2804; H01L 21/56; H01L 23/3107; H01L 23/49513; H01L 24/40; H01L 24/48; H01L 24/73; H01L 24/92; H01L 2224/40245; H01L 2224/48245; H01L 2224/73263; H01L 2224/73265; H01L 2224/92246; H01L 2224/92247

(57) ABSTRACT

A described example includes: a package substrate including a mounting pad, at least one die pad, a first set of conductive leads, and a second set of conductive leads spaced from the first set of conductive leads; a semiconductor die mounted to the at least one die pad with a first die attach material; a laminate transformer with integral magnetic material mounted on the mounting pad with a second die attach material; first electrical connections of wire bonds or ribbon bonds between the bond pads of the semiconductor die and the first set of conductive leads; second electrical connections of wire bonds or ribbon bonds between the bond pads of the semiconductor die and the laminate transformer with integral magnetic material; and mold compound covering the electrical connections, the semiconductor die, the laminate transformer with integral magnetic material and portions of the package substrate.

### TECHNICAL FIELD

This disclosure relates generally to semiconductor device packages with semiconductor dies and including integrated transformers.

### BACKGROUND

Semiconductor device circuits for power applications often include a transformer having coils isolated from one another by a core of dielectric material, but electromagnetically coupled to one another. In one example application a transformer can be used to transfer power across an electrical isolation barrier. By applying an alternating current (AC) signal to a primary coil, a corresponding AC signal is induced in a secondary coil by electromagnetic coupling, enabling the transfer of power across the isolation barrier. Recently, transformers have been integrated within a semiconductor device package.

In one approach, a transformer including isolated coils is formed on a laminate substrate with dielectric materials that can be mounted to a package substrate on a mounting pad. A bottom magnetic sheet material is first mounted to the die pad of the package substrate, the laminate is mounted to the bottom magnetic sheet, and a top magnetic sheet is mounted to the laminate. The magnetic sheets and the laminate are assembled using die attach film (DAF) material. Semiconductor dies are also mounted to the package substrate on additional die pads that are spaced from the transformer, and electrical connections can be made between the semiconductor dies and the transformer to form a circuit, while the semiconductor dies remain electrically isolated one from the other. A mold compound can be used to form a package body for the integrated devices to be provided in a semiconductor device package.

The mounting approach for the magnetic sheets and the laminate transformer in the approach described above requires multiple die attach deposition and die attach thermal cure steps. In addition, the magnetic sheets are spaced from the coils in the transformer by die attach material, and are spaced from one another by these materials and by the laminate, which can result in AC winding loss for the transformer, limiting efficient power transfer through the transformer.

In another approach, an “on-die” transformer is formed on a layer of dielectric deposited directly on a device side surface of a semiconductor die. This approach increases device integration, but is high in manufacturing cost, requires special processing in the semiconductor die manufacture process, and the resulting transformer is relatively low in efficiency. The size of the on-die transformer is also limited by the semiconductor die size, or alternatively, the use of the on-die transformer requires an increase in semiconductor die area, increasing die costs.

A reliable and robust semiconductor device package integrating a transformer for power applications, with high efficiency and at relatively low costs, is needed.

### SUMMARY

In a described example, a method includes: forming a package substrate having a board side surface and an opposite top surface, the package substrate having a first set of conductive leads, a second set of conductive leads electrically isolated from the first set of conductive leads, at least one die pad for mounting a semiconductor die, and a mounting pad for mounting a transformer that is spaced from the at least one die pad; mounting a semiconductor die on the at least one die pad using a first die attach material; mounting a laminate transformer with integral magnetic material on the mounting pad using a second die attach material; forming electrical connections of wire bonds or ribbon bonds between the bond pads of the semiconductor die and the first set of conductive leads on the package substrate; forming electrical connections of wire bonds or ribbon bonds between the bond pads of the semiconductor die and the laminate transformer with integral magnetic material; and covering the electrical connections, the semiconductor die, the laminate transformer with integral magnetic material and portions of the package substrate with mold compound.

In an additional described example, a method includes: forming a first conductor layer on a first surface of a dielectric core, and forming a second conductor layer on a second surface of the dielectric core opposite the first surface; patterning the first conductor layer to form a first coil on the first surface and patterning the second conductor layer to form a second coil on the second surface; depositing a magnetic material on the first surface in contact with the first coil, and depositing the magnetic material on the second surface in contact with the second coil; forming laminate layers of dielectric material over the first surface and the second surface, the laminate layers of dielectric material covering the first coil and the magnetic material over the first coil, and covering the second coil and the magnetic material over the second coil.

In another described example, an apparatus includes: a package substrate including a mounting pad, at least one die pad, a first set of conductive leads, and a second set of conductive leads spaced from the first set of conductive leads; a semiconductor die mounted to the at least one die pad with a first die attach material; a laminate transformer with integral magnetic material mounted on the mounting pad with a second die attach material; first electrical connections of wire bonds or ribbon bonds between the bond pads of the semiconductor die and the first set of conductive leads; second electrical connections of wire bonds or ribbon bonds between the bond pads of the semiconductor die and the laminate transformer with integral magnetic material; and mold compound covering the electrical connections, the semiconductor die, the laminate transformer with integral magnetic material and portions of the package substrate.

In a further described example, a transformer includes: a first coil formed in a first conductor layer on a first surface of a dielectric core, and a second coil formed in a second conductor layer on a second surface of the dielectric core opposite the first surface; a magnetic material on the first surface in contact with the first coil, and the magnetic material on the second surface in contact with the second coil; and laminate layers of dielectric material over the first surface and the second surface, the laminate layers of dielectric material covering the first coil and the magnetic material over the first coil, and covering the second coil and the magnetic material over the second coil.

### BRIEF DESCRIPTION OF THE DRAWINGS

FIGS. 1A-1B illustrate a semiconductor wafer and an individual semiconductor die, respectively.

FIGS. 2A-2B illustrate, in a top side projection view and a board side projection view, respectively, a semiconductor device package that is useful with an arrangement.

FIG. 3 illustrates, in a block diagram, an example circuit that can be formed within a semiconductor device package of an arrangement.

FIGS. 4A-4E illustrate, in a series of cross-sectional views, selected steps for forming a laminate transformer with integral magnetic material for use in various arrangements.

FIGS. 5A-5H illustrate, in a series of views including plan views and end views, selected steps for forming an example semiconductor device package of an arrangement.

FIG. 6 illustrates, in a flow diagram, an example method for forming a semiconductor device package of an arrangement.

FIG. 7 illustrates, in another flow diagram, an example method for forming a laminate transformer with integral magnetic material of an arrangement.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor die” is used herein. A semiconductor die can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor die can include passive devices such as resistors, inductors, filters, sensors, or active devices such as transistors. The semiconductor die can be an integrated circuit with hundreds or thousands of transistors coupled to form a functional circuit, for example a microprocessor or memory device. In example arrangements a semiconductor device package can include one or more semiconductor dies mounted on a package substrate. In particular examples, two semiconductor dies are mounted on a package substrate and electrically isolated one from another. A transformer is mounted to the package substrate that can transfer power between the semiconductor dies across an isolation barrier.

The term “semiconductor device package” is used herein. A semiconductor device package has at least one semiconductor die electrically coupled to terminals, and has a package body that protects and covers the semiconductor die. In some arrangements, multiple semiconductor dies can be packaged together. For example, a power metal oxide semiconductor (MOS) field effect transistor (FET) semiconductor die and a logic semiconductor die (such as a gate driver die or a controller die) can be packaged together to from a single packaged electronic device. Additional components such as passives can be included in the packaged electronic device.

The semiconductor die is mounted to a package substrate that provides conductive leads; a portion of the conductive leads form the terminals for the packaged device. The semiconductor die can be mounted to the package substrate with a device side surface facing away from the substrate and a backside surface facing and mounted to a die pad of the package substrate. In wire bonded semiconductor device packages, bond wires couple conductive leads of a package substrate to bond pads on the semiconductor die. The semiconductor device package can have a package body formed by a mold compound that is a thermoset epoxy resin formed in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions provide the terminals for the semiconductor device package.

In packaging semiconductor devices, mold compound may be used to partially cover a package substrate, to cover the semiconductor die, and to cover the electrical connections from the semiconductor die to the package substrate. This can be referred to as an “encapsulation” process, although some portions of the package substrates are not covered in the mold compound during encapsulation. For example, terminals and leads are exposed from the mold compound. Encapsulation is often a compressive molding process, where thermoset mold compound such as epoxy resin can be used. A room temperature solid or powder mold compound can be heated to a liquid state, and then molding can be performed by pressing the liquid mold compound into a mold. Transfer molding can be used. Unit molds shaped to surround an individual device may be used, or alternatively block molding may be used to form the packages simultaneously for several devices from mold compound. The devices can be provided in an array of several, hundreds or even thousands of devices in rows and columns that are molded together. After the molding, the individual packaged devices are cut from each other in a sawing operation by cutting through the mold compound and package substrate in saw streets formed between the devices.

The term “package substrate” is used herein. A package substrate is a substrate arranged to receive a semiconductor die and to support the semiconductor die in a completed semiconductor device package. Package substrates useful with the arrangements include conductive leadframes, which can be formed from copper, aluminum, stainless steel, steel and alloys such as Alloy 42 and copper alloys. The leadframes can be provided in strips or arrays. The conductive leadframes can be provided as a panel with strips or arrays of unit device portions in rows and columns. Semiconductor dies can be placed on respective unit device portions within the strips or arrays. A semiconductor die can be placed on a die mount area for each packaged device, and die attach or die adhesive can be used to mount the semiconductor dies to the die mount areas. In wire bonded packages, bond wires can couple bond pads on the semiconductor dies to the leads of the leadframes. The leadframes may have plated portions in areas designated for wire bonding, for example silver plating can be used. After the bond wires are in place, a portion of the package substrate, the semiconductor die, and at least a portion of the die pad can be covered with a protective material such as a mold compound.

The term “electrically isolated” is used herein. In an example arrangement, a package substrate has a first group of conductive leads and a second group of conductive leads, and has a first die pad for a semiconductor die, a second die pad spaced from the first die pad for a second semiconductor die, and a mounting pad spaced from the second die pad for a transformer. By spacing the conductive elements apart and grouping the conductive leads in to a first group and a second group, two electrically isolated voltage regimes are formed, one for connection to the first semiconductor die, and one for connection to the second semiconductor die. Each voltage regime has its own voltage and ground potential connections that are not connected to the voltage and ground potentials of the other voltage regime, providing electrical isolation between an input side and an output side of the packaged device. In an example arrangement using a transformer and an electrically isolated leadframe to mount two isolated semiconductor dies, the transformer is electrically isolated from the package substrate while one coil of the transformer is coupled to one of the semiconductor dies, and another coil of the transformer is coupled to the other one of the semiconductor dies, allowing for transfer of energy across the isolation barrier formed by the transformer core using electromagnetic coupling between the coils. The two semiconductor dies are coupled to voltages and grounds in the two isolated voltage regimes.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser or other cutting tool to pass between the molded electronic devices to separate the devices from one another. This process is another form of singulation. When the molded electronic devices are provided in a strip with one device adjacent another device along the strip, the saw streets are parallel and normal to the length of the strip. When the molded electronic devices are provided in an array of devices in rows and columns, the saw streets include two groups of parallel saw streets, the two groups are normal to each other and the saw will traverse the molded electronic devices in two different directions to cut apart the packaged electronic devices from one another in the array.

The term “quad flat no-lead” or “QFN” is used herein for a type of electronic device package. A QFN package has conductive leads that are coextensive with the sides of a molded package body, and in a quad package the leads are on four sides. Alternative flat no-lead packages may have leads on two sides or only on one side. These can be referred to as “small outline no-lead” or “SON” packages. No-lead packaged electronic devices can be surface mounted to a board. Leaded packages can be used with the arrangements where the leads extend away from the package body and are shaped to form a portion for soldering to a board. A small outline package (SOP) can be used with the arrangements. Leads for leaded packages are arranged for solder mounting to a board. The leads can be shaped to extend towards the board, and form a mounting surface. Gull wing leads, J-leads, and other lead shapes can be used. A small outline integrated circuit (SOIC) package with leads can be used with the arrangements. Wide SOIC packages can be used with the arrangements. Dual in-line packages (DIPs) can be used. In DIPs, the leads end in pin shaped portions that can be inserted into conductive holes formed in a circuit board, and solder is used to couple the leads to the conductors within the holes.

The term “magnetic material” is used herein. A magnetic material useful with the arrangements includes iron oxide, Fe₂O₃, additional useful examples include nickel ferrite (NiFe), nickel zinc ferrite (NiZnFe), and manganese zinc ferrite (MnZnFe). Ferrites are ferrimagnetic, and become magnetized in the presence of a magnetic field.

The term “laminate transformer with integral magnetic material” is used herein. In example arrangements, a transformer including at least a primary coil and a secondary coil is formed on a first surface and a second opposite surface of a dielectric core. The term “planar coil” is used herein. A planar coil is a coil of conductor formed of a continuous conductor that forms a coil lying in a common plane, such as a horizontal or vertical plane. In the example arrangements, the primary or first coil and the secondary or second coil are conductors patterned to form planar coils, the conductors can be, for example, copper or copper alloy forming the planar coils. The first and second coils can be aligned to one another to form a transformer. Additional laminate layers of dielectric material covers both surfaces of the dielectric core and the coils to complete a laminate transformer. In the example arrangements, a magnetic material is deposited over the first and the second coils and in contact with the coil conductors. In an example arrangement, the magnetic material is deposited as a magnetic paste or as a magnetic ink using stencil, drop-on-demand or inkjet printing techniques. In an advantage of the arrangements, the magnetic material is deposited on and in contact with the coil conductors without any intervening materials or spaces (in contrast to prior approaches using magnetic films or sheets mounted over the surfaces of a laminate transformer.)

In example arrangements, a leadframe with isolated lead portions can be used as a package substrate. The leadframe has two electrically isolated portions with a first group of conductive leads configured for coupling a DC output voltage to a load, and with a second group of conductive leads for coupling to a DC input voltage. A laminate transformer with integral magnetic material of the arrangements is mounted to a mounting pad of the leadframe, and provides an isolation barrier between devices coupled to the DC input voltage and devices coupled to provide the DC output voltage. A primary side driver circuit is provided on a first semiconductor die mounted to a first die pad on the leadframe, and a secondary side rectifier circuit is provided on a second semiconductor die mounted to a second die pad on the leadframe, the two semiconductor dies are electrically isolated one from the other. Electrical connections are made between the semiconductor dies and the coils of the transformer to form an integrated DC-DC converter as a packaged semiconductor device with an integrated laminate transformer. In the arrangements, the laminate transformer includes integral magnetic material within the dielectric layers of the laminate transformer. As shown in example arrangements described below, the laminate transformer is a passive component that can be effectively used within a semiconductor device package. Alternatively, the laminate transformer can be mounted on or to a semiconductor device package, or mounted to a board or module to provide a transformer.

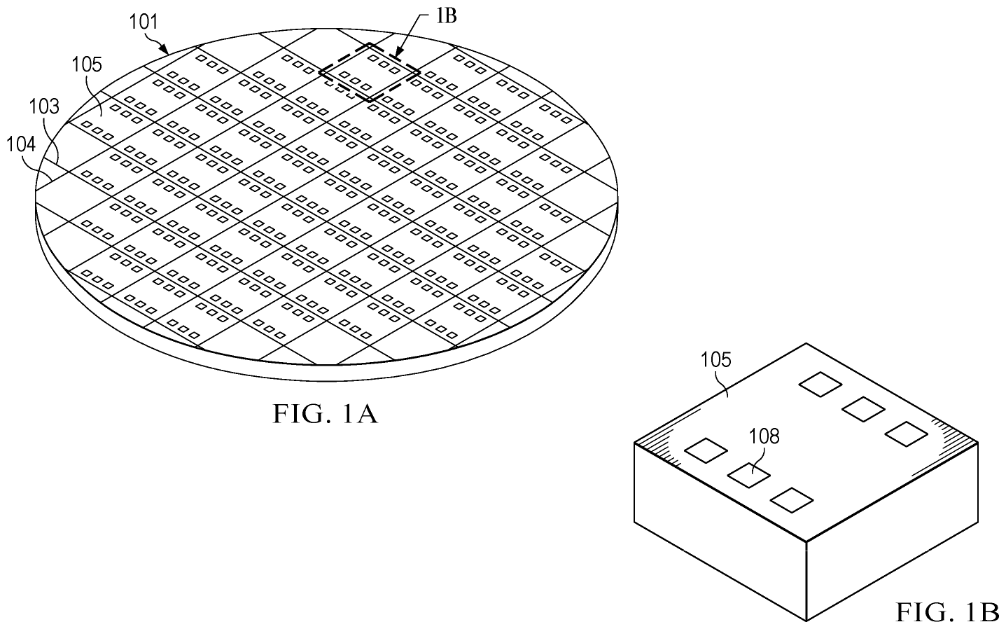

FIGS. 1A-1B illustrate in two projection views a semiconductor wafer and an individual semiconductor die, respectively. In FIG. 1A, semiconductor wafer 101 is shown with an array of semiconductor dies 105 arranged in rows and columns. The semiconductor dies 105 are formed using manufacturing processes in a semiconductor manufacturing facility, including ion implantation for carrier doping, anneals, oxidation, dielectric and conductor deposition, photolithography, pattern, etch, chemical mechanical polishing (CMP), electroplating, damascene plating, and other processes for making semiconductor devices. Devices are formed on a device side surface of the semiconductor dies. Scribe lanes 103 and 104, which are perpendicular to one another and which run in parallel groups across the semiconductor wafer 101, separate the rows and columns of the completed semiconductor dies 105, and provide areas for dicing the semiconductor wafer 101 to separate the semiconductor dies 105 from one another.

FIG. 1B illustrates a single semiconductor die 105, with bond pads 108, which are conductive pads that are electrically coupled to devices (not shown for simplicity) formed in the semiconductor dies 105. After the semiconductor wafer is completed in a semiconductor fab, the semiconductor dies 105 are separated from semiconductor wafer 101 by wafer dicing, or are singulated from one another, using the scribe lanes 103, 104 (see FIG. 1A). Wafer dicing can be done by a mechanical saw, by ablative laser cutting, by a stealth laser process forming stress dislocation areas along the scribe lanes, or by using a plasma dicing process to etch through or partially through the semiconductor wafer in the scribe lanes. When the wafer is etched partially or is processed using stealth laser dicing, an expansion dicing tape can be used and the dies can be pulled apart along the scribe lanes to complete the singulation.

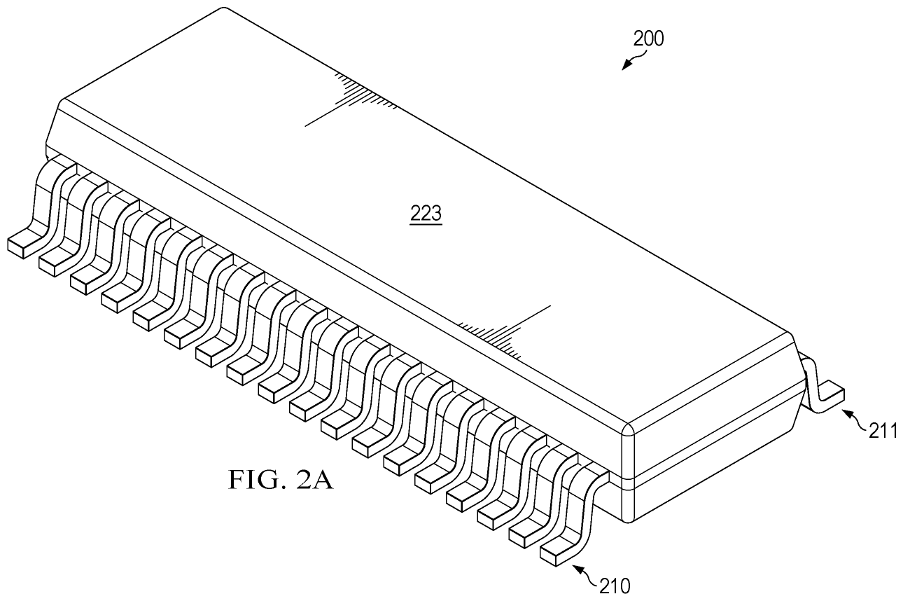

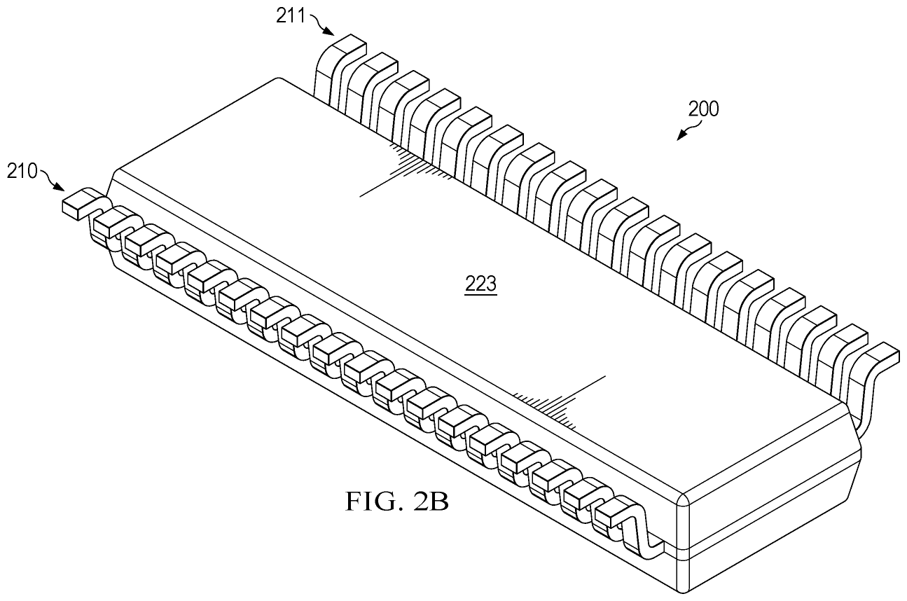

FIGS. 2A-2B illustrate, in a top-side projection view and a board side projection view, respectively, an example semiconductor device package 200 that can be used with the arrangements. In FIG. 2A, the view is from the top side of the semiconductor device package 200 and a mold compound 223 forms a package body, while terminals 210 and 211 are shown. In this example semiconductor device package 200, portions of the terminals 210, 211 are shaped to form leads that extend external to the mold compound 223 that forms the package body and the leads are shaped to provide feet portions for mounting the semiconductor device package 200 to a board or module, for example by using surface mount technology (SMT) soldering processes.

In FIG. 2B a board side view of the semiconductor device package 200 is shown. The mold compound 223 is shown with the first group of leads 210 shown on one side and the second group of leads 211 shown on the opposite of two sides of the leaded package. In alternative arrangements, “no-lead” packages such as a quad flat no-lead (QFN) package can be used. No-lead packages can be surface mounted to a circuit board using less board area, as the terminals are formed within the boundaries of the mold compound package, in contrast to leaded packages such as semiconductor device package 200, where leads extend from the mold compound package to reach the board or module.

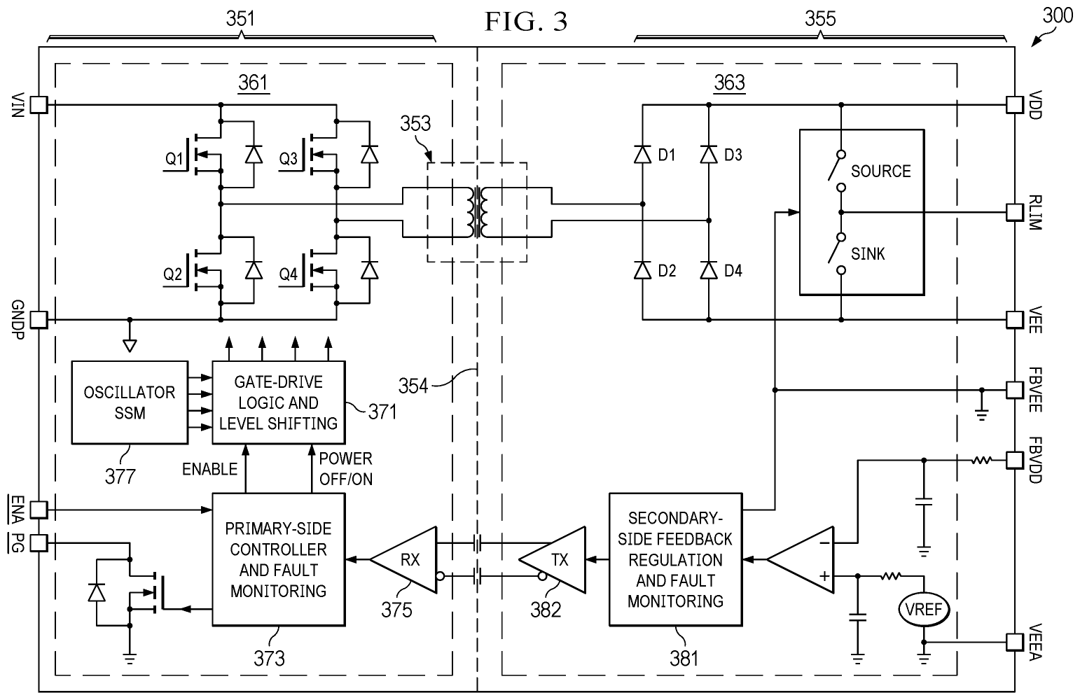

FIG. 3 illustrates, in a block diagram, a circuit 300 that can be used with an example arrangement. The circuit 300 includes devices configured to be coupled to a supply voltage VIN and a ground GNDP in a first voltage regime 351, and devices configured to be coupled to an output voltage VDD and a ground or negative voltage VEE in a second voltage regime 355. A primary side driver 361 is coupled to a primary coil of a transformer 353, while a secondary side driver 363 is coupled to a secondary coil of the transformer 353. An isolation barrier 354 (a dashed line in FIG. 3) indicates that an input side (in the first voltage regime 351) and an output side (in the second voltage regime 355) of the circuit 300 are electrically isolated. The example circuit 300 forms a DC-DC converter. Applications for the DC-DC converter 300 include charging batteries, charging electronic vehicles, in automotive systems, and as power supplies for various portable devices that include batteries such as laptop computers, mobile phones, smart tablets, web browsing devices, games, video and audio equipment, meters, and many other devices where electrical isolation is needed between DC voltages of different levels.

In FIG. 3, the primary side driver 361 includes active devices Q1-Q4 which can be, for example, power FET devices, a spread spectrum modulation (SSM) oscillator 377, gate drivers and voltage level shifters 371, and a primary side controller 373. In operation, the active devices Q1-Q4 are selectively switched on and off at a relatively high frequency to supply an alternating current (AC) to a primary side coil of the transformer 353. The AC current can be developed from a DC supply voltage at the input terminal VIN, for example. A feedback receiver amplifier 375 provides an output voltage monitoring system to enable the primary side controller 373 to use pulse width modulation or frequency modulation with oscillator 377 to control the active devices Q1-Q4 to increase or decrease power to the transformer 353 and to regulate an output, the DC voltage VDD.

The secondary side driver 363 is a passive rectifier with diodes D1-D4 providing a DC output from the AC current flowing in a secondary coil of the transformer 353. The secondary side regulator 381 controls switches to regulate the output voltages VDD and VEE. Feedback inputs FBVEE, FBVDD are used to monitor the output voltages for regulation. Feedback transmit amplifier 382 is capacitively coupled across the isolation barrier 354 to feedback receiver amplifier 375.

In an implementation used in an example arrangement, the primary side driver 361 is provided in a first semiconductor die, the secondary side driver 363 is provided in a second semiconductor die, and the transformer 353 is provided as a laminate transformer with integral magnetic material. The three devices are then mounted to a package substrate, such as leadframe with electrical isolation, and are used to form a semiconductor device package with an integrated laminate transformer.

In additional alternative arrangements, a laminate transformer with integral magnetic material can be mounted to a package substrate, and at least one semiconductor die can be mounted to the package substrate and electrically connected to the transformer. An integrated semiconductor device package with a laminate transformer is then formed.

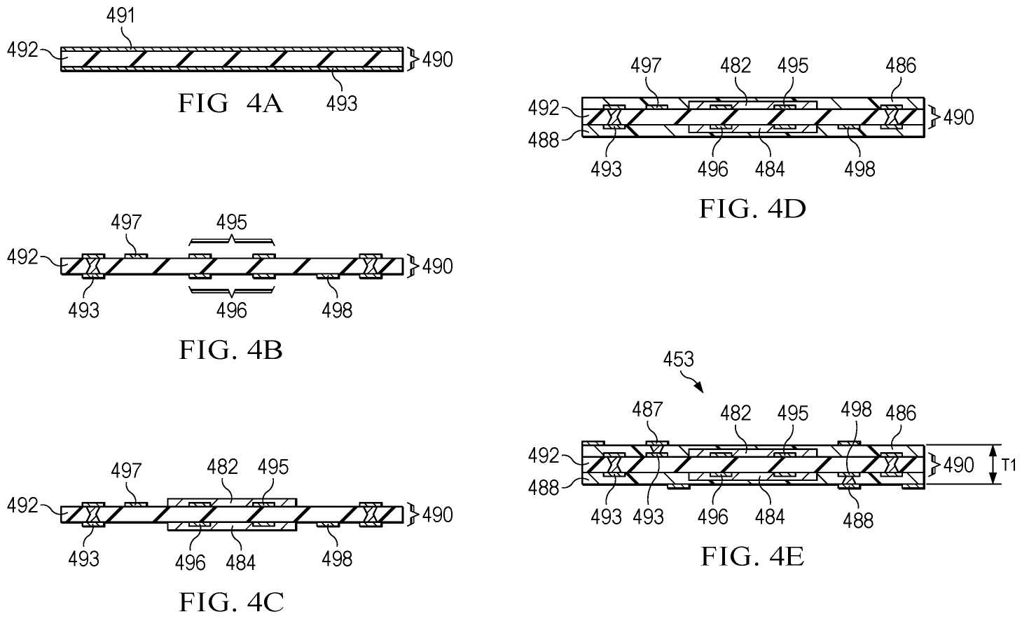

FIGS. 4A-4E illustrate, in a series of cross-sectional views, selected steps for forming a laminate transformer with integral magnetic material for use in various arrangements. The laminate transformer with integral magnetic material forms a passive component that can also be used as a transformer component in various applications.

In FIG. 4A, a substrate 490 is shown in a cross-sectional view. The substrate 490 has a dielectric core 492, which can be in one example a bismaleimide triazine (BT) core. Alternative materials for the dielectric core 492 include Ajinomoto build-up film (ABF), which is a dielectric film used for forming circuit boards that is commercially available from Ajinomoto Fine Techno Co. Inc. of Tokyo, Japan. The dielectric core 492 can also be formed of a ceramic, semiconductor, or epoxy. Embedded Trace Substrate (ETS) materials can be used including ABF, or BT resin, as the core 492, and pre-impregnated (“prepreg”) insulating materials for other dielectric layers. A first conductor layer 491 is formed on a first surface of the core 492, while a second conductor layer 493 is formed on a second opposite surface. The conductor layers 491, 493 can be formed by plating or by film deposition. Copper conductor layers or copper alloy conductor layers can be used. A direct bonded copper (DBC) substrate with copper deposited on opposite sides of a ceramic core can be used to form core 492 and the conductor layers 491, 493. Ajinomoto build up film (ABF) can be used to form a multilayer package substrate with the copper conductor layers on opposite sides of a core formed of the ABF dielectric. Alternatively, ABF can be used to form dielectric material over the coils as is described below, with a BT resin or other dielectric forming the core 492.

In FIG. 4B, the substrate 490 of FIG. 4A is shown after the first conductor layer 491 and the second conductor layer 492 (see 491, 492 in FIG. 4A) have been patterned. First conductor layer 491 (see FIG. 4A) is patterned to form a first coil (for example, a primary side coil) 495 and the second conductor layer 492 (see FIG. 4A) is patterned to form a second coil 496 (for example a secondary side coil) for the laminate transformer. The coils 495 and 496 can be planar coils with a spiral pattern, for example, and can be aligned to one another to operate as a transformer. The coils 495, 496 are formed on opposite surfaces of the core 492, which is a dielectric material, and the coils are electrically isolated from one another by the dielectric core 492. Additional conductors such as 497, 498 are patterned to provide electrical connections to the coils 495, 496. Through-vias such as through-via 493 can be formed to provide connections on one side of the core 492 for connecting to a coil on the opposite side of core 492, for example.

FIG. 4C illustrates, in another cross-sectional view, the elements of FIG. 4B after magnetic material is deposited on the substrate 490. As shown in FIG. 4C, magnetic material layer 482 is deposited on the first coil 495 and magnetic material layer 484 is deposited on the second coil 496. The core 492, the conductors 497, 498 and the through-vias such as 493 are again shown as in FIG. 4B. The magnetic material layers 482 and 484 are of the same material.

In an example arrangement, the magnetic material layers 482, 484 are a magnetic paste. Magnetic pastes useful in the arrangements are commercially available from Ajinomoto Fine-Techno Co. Inc., of Japan, for example. The magnetic pastes can be supplied as an ink with a solvent or as a liquid and can be deposited by vacuum screen printing, screen printing, by stencil, by ink jet printing or by drop-on-demand deposition. The magnetic material used in example arrangements is compatible with laminating films such as ABF and with prepreg processes.

FIG. 4D illustrates, in a further cross-sectional view, the elements of FIG. 4C after additional processing. In FIG. 4D, dielectric layers 486, 488 are shown formed over the surfaces of the core 492 and covering the magnetic material 482 over the first coil 495, and the magnetic material 484 over the second coil 496. In one example process, Ajinomoto Build-up Film (ABF), which is commercially available from Ajinomoto Fine Techno Co. Inc., of Japan, can be used. The ABF films can be applied by positioning the films over the substrate 490, applying heat to soften the films, and applying a vacuum that causes the softened film to conform to the structures beneath the film. The ABF can then be cured to form a solid layer and the solid ABF can be processed by grinding to planarize the outer surface, and can be plated on. The ABF can be applied in multiple layers by repetitive processing. Conductor seed layer deposition, photolithography, plating, and patterning can be used to form conductor layers between or on layers of the ABF film. Vias can be formed through dielectric layers formed by ABF film. In an alternative process, a prepreg material can be used to form the layers 486, 488 over the substrate 490. In a prepreg laminate, a glass reinforced woven fabric is coated with a resin to form a pre-impregnated (“prepreg”) film which can be applied over the substrate and then cured to form the dielectric layers. Copper foils can be applied to the prepreg dielectric to form conductor layers, these conductor layers can be patterned to form traces.

FIG. 4E illustrates, in another cross-sectional view, the elements of FIG. 4D after an additional processing step forms a laminate transformer 453 with integral magnetic material that can be used with an example arrangement. In FIG. 4E, the transformer 453 includes the first coil 495 and the second coil 496 on opposite sides of a dielectric core 492 on a substrate 490. Magnetic material layers 482, 484 are shown deposited over and in contact with the first and second coils 495, 496, respectively. Dielectric layers 486 and 488 cover the magnetic material. Conductive traces 487, 488 form connection points for the coils 495, 496 and can include conductive vias that extend vertically through the dielectric layers 486, 488. In an example arrangement, ABF processing is used to form the dielectric layers 486, 488. Metal plating and patterning including deposition of a seed layer, patterning the seed layer, and plating metal to form the conductors 487, 488 can be used. The transformer 453 can be one unit of many units formed simultaneously on substrate 490, which can be divided into unit transformers arranged in rows and columns and spaced from one another by saw lanes. Because the magnetic material is integral to the laminate transformer, the arrangements provide a relatively thin transformer (when compared to mounting magnetic sheets or magnetic films on the exterior surfaces of a laminate transformer). In an example, the laminate transformer including the integral magnetic material has a thickness of 380 to 420 microns, enabling a relatively thin semiconductor device package that incorporates the laminate transformer.

The laminate transformers such as 453 can be formed at a different time and place than the semiconductor dies used in a semiconductor device package, for example transformer 453 can be formed by a substrate manufacturer and delivered for use in a panel or array that can be singulated at a packaging site. Alternatively, the transformers such as 453 can be provided as components in individual units ready for substrate mounting.

While the transformer 453 is shown in the example arrangements described herein as mounted within a semiconductor device package, the transformer 453 is a passive component and can be mounted externally on or to a semiconductor device package, can be used in a stacked package arrangement, or can be mounted on a circuit board or module to provide a transformer component.

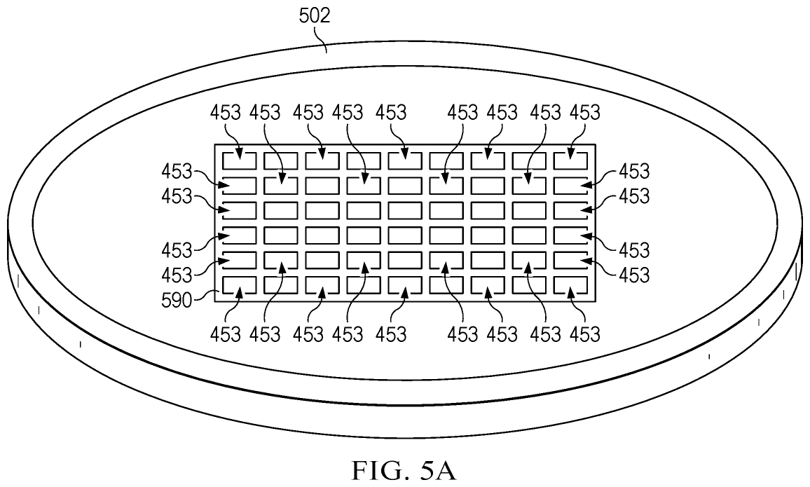

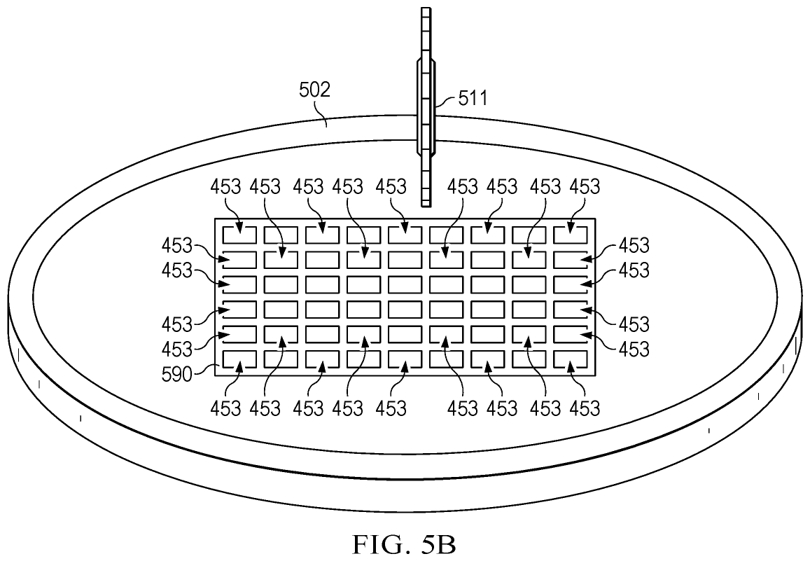

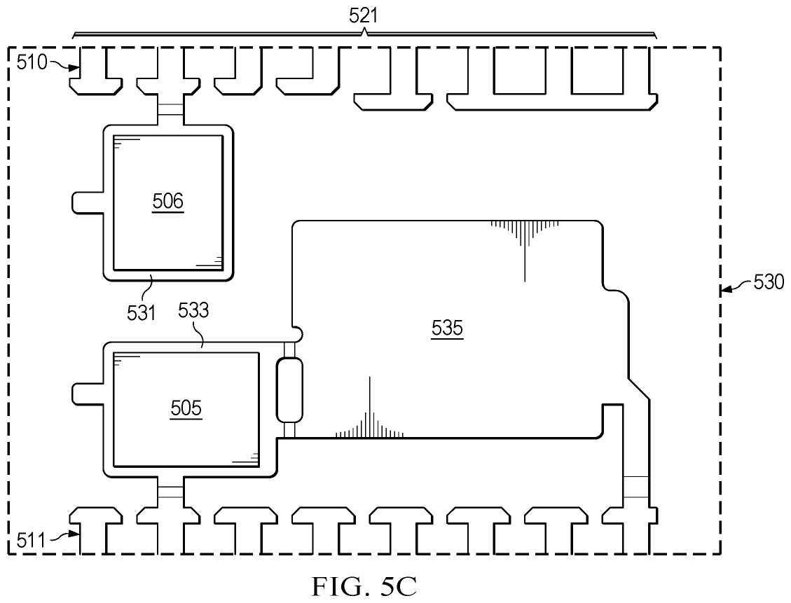

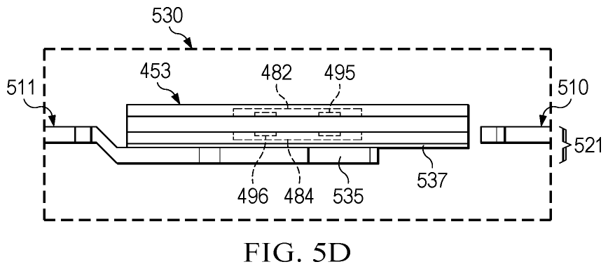

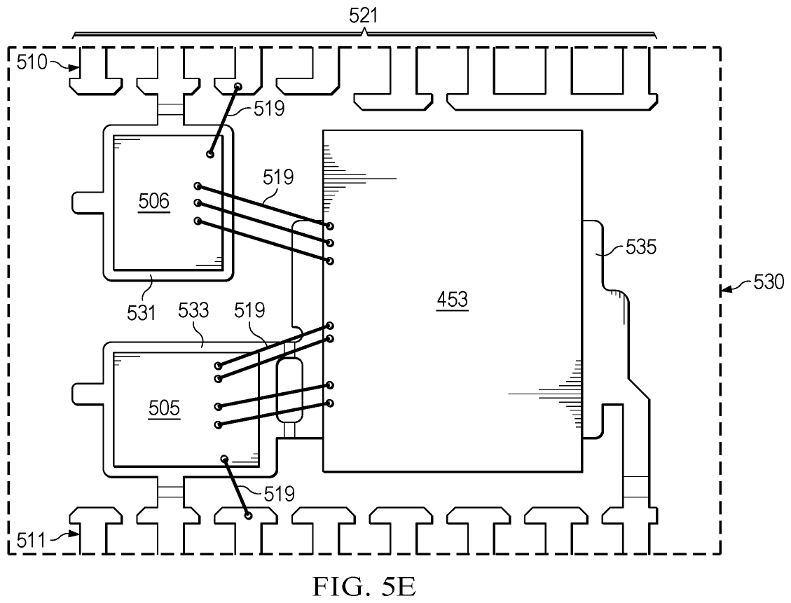

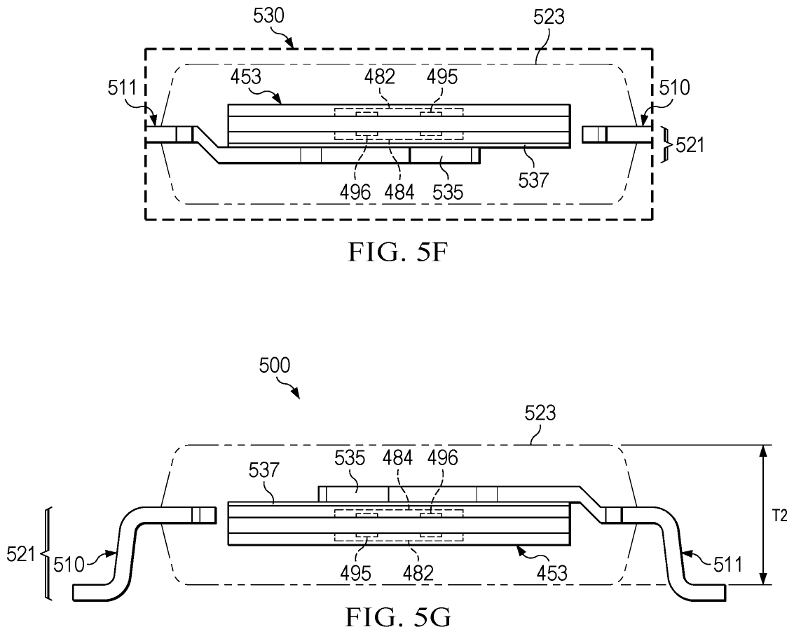

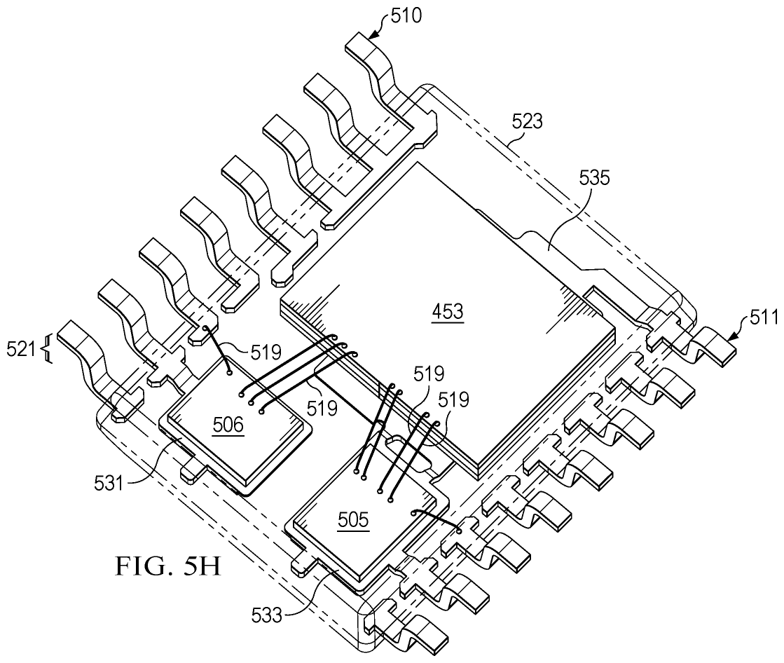

FIGS. 5A-5H illustrate, in a series of plan views and end views, selected steps for forming a semiconductor device package with an integrated laminate transformer in an example arrangement.

FIGS. 5A-5B illustrate example dicing steps used to singulate unit transformers (see transformer 453 in FIG. 4E, for example) from a substrate panel having multiple unit transformers such as 453 formed using, for example, using steps such as those illustrated in FIGS. 4A-4E, and described above. In FIG. 5A, a dicing frame 502 is shown with a substrate 590 (that is similar to substrate 490 in FIG. 4E, for example) mounted thereon. Substrate 590 has unit transformers 453 formed in rows and columns, each unit transformer 453 is a laminate transformer that includes integral magnetic materials over coils (see magnetic material layers 482, 484 over a first coil 495 and a second coil 496 in FIG. 4E, for example.) The dicing frame 502 has an adhesive film that removably adheres to and supports substrate 590 during a sawing operation described below.

In FIG. 5B, the elements of FIG. 5A are shown while a sawing operation is illustrated to singulate the unit transformers 453 from the substrate 590. In FIG. 5B, the substrate 590 is cut into individual units 453 by a mechanical saw 511 that cuts through the substrate 590 and traverses the substrate 590 in saw streets between units. The dicing frame 502 holds and supports the individual unit transformers 453 after the sawing operation, so that a pick and place tool can retrieve the unit transformers 453 from the dicing frame 502 for further processing.

The singulation steps shown in FIGS. 5A-5B can be performed asynchronously with respect to the packaging steps shown in FIG. 5C-5H, described below, and the transformer singulation can be performed at the same location, or at a different site, than the other remaining steps. The unit transformers 453 can be provided as individual components already singulated from the substrate 590, or as shown here, the substrate 590 can be provided and used at the packaging site, and then singulated prior to the remaining steps.

FIGS. 5C-5H illustrate, in a series of side views and plan views, selected steps used in forming an example arrangement of a semiconductor device package including the transformers with integral magnetic material.

In FIG. 5C, a package substrate, in this example a leadframe 521 with electrically isolated portions, is shown in a plan view from a board side. Line 530 indicates that only a portion of the leadframe 521 is shown, with the leads 510, 511 shown extending to line 530, these portions of the leads 510, 511 will be covered by mold compound as described below, the remainder of the leads 510, 511 are not shown in FIGS. 5C-5F, (but see 510, 511 in FIGS. 5F-5G). Leads 510 and leads 511 are configured to be coupled to isolated voltage regimes, so that these conductive leads are not electrically coupled. In an example process, the leadframe 521 can be a unit device that is part of a leadframe array or strip with many unit devices spaced from one another and temporarily tied together with tie bars (not shown). By processing multiple units simultaneously in the packaging processes, throughput is increased and costs are lowered. Once the semiconductor device packages are completed, the leadframe strip or leadframe array is cut into unit semiconductor device packages by cutting through the leadframe in saw streets between the completed devices.

Semiconductor dies 505 and 506 are shown mounted to die pads 533 and 531, respectively, on the package substrate 521. The semiconductor dies 505, 506 can be mounted using a die attach material such as a conductive die attach film (CDAF) or a conductive die attach paste (note, the die attach material is not visible in FIG. 5C, as it lies beneath the semiconductor dies 505, 506). Semiconductor dies 505, 506 can be similar to semiconductor die 105 in FIGS. 1A-1B, for example. The semiconductor die 505 can implement a primary side driver device similar to the primary side driver 361 in FIG. 3. The semiconductor die 506 can implement a second side driver device similar to the secondary side driver 363 in FIG. 3. After the die attach is used to mount the semiconductor dies 505, 506, the die attach can be cured in a thermal process using an oven, for example. Because the leadframe 521 has two isolated die pads 533, 531 for mounting the semiconductor dies 505, 506, the two die pads 533, 531 can be coupled to isolated grounds or other potentials to provide a potential coupled to the backsides of the semiconductor dies 505, 506. A mounting pad 535 is also shown, which is configured to receive a laminate transformer such as transformer 453 (not shown, see FIG. 4E).

FIG. 5D illustrates, in an end view, the elements of FIG. 5C after an additional process step. In FIG. 5D, the leadframe 521 is shown from an end view with the line 530 indicating it is a partial view of the leadframe. The transformer 453 is shown with coils 495, 496 spaced by dielectric material (see core 492 in FIG. 4E, for example) and magnetic material 482, 484 over the coils 495, 496 in transformer 453. The transformer 453 is mounted to the mounting pad 535 using a non-conductive die attach film (NCDAF) or a non-conductive die attach paste 537. After the transformer 453 is mounted, a die attach cure is performed in an oven, for example. The leads 511 extend to one side of the leadframe 521 while the leads 510 extend to another side of the leadframe 521 and are electrically isolated from the leads 510 and from the mounting pad 535. One or more of the leads 511 may be coupled to the mounting pad 535, however by use of the non-conductive die attach film 537, the transformer 453 is electrically isolated from the mounting pad 535.

FIG. 5E illustrates, in another plan view from the board side, the elements of FIG. 5D, after additional processing. In FIG. 5E, a first group of wire bonds 519 are shown electrically coupling the semiconductor die 505 to leads 511 and to the transformer 453. Additional wire bonds 519 are shown coupling semiconductor die 506 to leads 510 and to the transformer 453. The dashed line 530 indicates the leadframe 521 is shown in a partial view, the leads 510, 511 are shown ending at the line 530, but extend beyond it as described below. The semiconductor dies 505, 506 and the leads 510, 511 are electrically isolated from one another. Transformer 453 and the leadframe provide an isolation barrier.

To transition from the elements as shown in FIG. 5D to the wire bonded elements of FIG. 5E, several processes are performed. After the transformer 453 is mounted to the mounting pad as shown in FIG. 5D, a clean step is performed to prepare the elements for a wire bonding process. In an example a plasma cleaning step is performed to remove debris, excess die attach, and unwanted particles from the devices. A wire bonder tool is then used to form the wire bonds 519 between the semiconductor dies 505, 506 and the transformer 453, and between the semiconductor dies 505, 506 and the leads 510, 511.

In an example process that uses a thermosonic wire bonding tool, a bond wire extends a short distance through an opening in a capillary. The capillary can be a ceramic, for example. A bond wire supply, such as an automated spool, can provide the bond wire that feeds to the capillary. A flame or electric arc is applied to the exposed end of the bond wire. This melts the end of the bond wire and forms a ball, referred to as a “free air ball”, at the end of the bond wire. The molten ball is placed in contact with a bond pad on a semiconductor device. The capillary is vibrated by sonic energy applied to the capillary while the molten ball is simultaneously mechanically pressed against the bond pad. Thermal processing is used by heating the devices during wire bonding. Thus, a combination of thermal energy, mechanical pressure, and sonic energy is used to form a “ball bond” between the molten ball and the bond pad. The capillary then moves away from the ball bond, allowing the bond wire to extend through the capillary opening as it moves. By use of clamps that can grab the bond wire and then release it, and by the motion of the capillary relative to the devices, the bond wire can be shaped and forms an arc shape extending from the ball bond above the devices. The capillary moves the bond wire to a conductive pad on the transformer, or to a conductive portion of a lead, to make the other connection of the wire bond. A “stitch” bond is formed by pressing the bond wire against the conductive pad or against the lead and applying mechanical pressure, sonic energy and again thermal energy. The capillary is then moved a short distance from the stitch bond and the bond wire is broken or cut to form a new exposed end extending from the capillary. This bonding cycle is automated and can be repeated several times a second to rapidly form the wire bond connections needed between both semiconductor dies, the leads, and the transformer.

The bond wires 519 can be, in useful examples, copper, copper alloys, palladium coated copper (PCC), gold, silver and aluminum. When copper bond wire or PCC is used, the wire bonding tool may have an anoxic atmosphere, the anoxic atmosphere helps to deter oxidation and tarnish of the copper bond wires (which can be accelerated at elevated temperatures used in wire bonding.)

Alternatives to wire bonding include ribbon bonding to form the electrical connections between the semiconductor dies and the leads, and between the semiconductor dies and the transformer. In ribbon bonding, conductive ribbons are placed on the bond pads and the conductive leads and are bonded to them to form the electrical connections.

FIG. 5F illustrates, in an end view, the elements of FIG. 5E after additional processing. FIG. 5F is shown with the board side of the leadframe 521 facing upwards for convenience of illustration. In FIG. 5F, a mold compound 523 is shown formed over the leadframe 521, and covering the transformer 453, and portions of the leads 510 and 511. The mold compound also covers the semiconductor dies 505, 506 (see 505, 506 in FIG. 5E) which are not visible in the view of FIG. 5F. Note that in FIG. 5F, the wire bonds 519 are not shown for simplicity of illustration (see wire bonds 519 in FIG. 5E, for example).

The mold compound 523 can be formed in a transfer molding process using a thermoset epoxy resin mold compound, sometimes referred to as “EMC” or “electronic mold compound.” In an example process, the leadframe 521 and the other elements attached to it, including the semiconductor dies 505, 506, the bond wires 419, and the transformer 453 are placed in a chase of a transfer mold tool. In an example process, mold compound can be provided in a solid state as a powder or as a puck of solid material (solid at room temperature). The mold compound is placed in the mold tool and heated to a liquid, and using hydraulic pressure, the liquid mold compound is forced through runners into the cavities of the mold chase and surrounds the leadframe 521 and the other elements, while external portions of the leads 510, 511 (not shown in FIG. 5F, see FIG. 5G below) are positioned so as to remain uncovered by the mold compound. The mold compound is then cured to form a solid package body.

FIG. 5G illustrates, in another end view, the elements of FIG. 5F after additional process steps are used to form a semiconductor device package 500 of an example arrangement. Note that in FIG. 5G the leadframe 521 is rotated with respect to FIG. 5F, for example. In FIG. 5G, the leadframe 521 is shown now oriented with the board side down, oriented as the semiconductor device package 500 will be mounted to a board or module. Because the leadframe 521 is shaped to rise away from the board side surface when traversing the leadframe from the ends of the leads 510, or 511, to the interior of the package, it can be referred to as an “upset” type leadframe. In an alternative arrangement, the devices can be mounted on the top surface of a “downset” leadframe, which is shaped to fall towards the board side surface when traversing from the ends of the leads to the interior of the package. The transformer 453 is shown facing the board side of the semiconductor device package 500 and mounted to the mounting pad 535 by non-conductive die attach film 537. Note that the semiconductor devices 505, 506 are not visible in the end view of FIG. 5G (see FIG. 5H where semiconductor devices 505 and 506 are shown in a projection view). The leads 510, 511 have portions outside the package body formed by mold compound 523, the example semiconductor device package 500 is a leaded device package. In alternative arrangements, “no-lead” packages such as quad flat no-lead (QFN) packages can be used. In the example shown in FIG. 5G, the leads 510, 511 have been shaped in a “trim form” tool to have ends that are arranged for surface mount technology (SMT) mounting to a board using solder, for example, to mount the ends of leads 510, 511 to conductive traces on a circuit board. The transformer 453 includes coils 495, 496 that are covered by magnetic material 482, 484 and the magnetic material 482 and 484 is covered by laminated dielectric material so that transformer 453 is a laminate transformer with integral magnetic material. By use of the arrangements, the magnetic material 482, 484 is advantageously in contact with the coils 495, 496 which increases performance over prior approaches (where magnetic films or sheets are applied over a laminate transformer but spaced from the coils, the magnetic materials in those prior approaches are spaced from the coils and from each other by the laminate dielectrics and by die attach layers, reducing performance of the transformer). As shown in FIG. 5G, the semiconductor device package has a thickness labeled “T2.” In an example, the thickness T2 can range between 2.3 to 3.2 millimeters, including the laminate transformer and the leadframe. Because the laminate transformer with integral magnetic materials has a relatively low thickness (see FIG. 4E, thickness “T1”, which can range from 380 to 420 microns), use of the arrangements advantageously enables a relatively thin semiconductor device package.

Use of the laminate transformer with integral magnetic materials advantageously substantially reduces the steps needed to assemble the semiconductor device package 500, and reduces the cost of assembly over prior approaches, while yet improving device performance over the prior approaches. The thickness of the semiconductor device package 500 can be reduced because the magnetic materials are integral to the laminate transformer 453, instead of being applied over a laminate transformer component. The number of die attach and cure steps needed to assemble semiconductor device packages using the arrangements is reduced (when compared to a prior approach applying magnetic films or strips to a laminate transformer) during package assembly, lowering costs.

FIG. 5H illustrates, in a projection view looking from a board side, the semiconductor device package 500 of FIG. 5G, shown with the mold compound 523 shown as transparent so the interior elements are visible.

The mold compound 523 forms a package body for the semiconductor device package 500, and covers the semiconductor die 505, the semiconductor die 506, the transformer 453, the die pads 531 and 533, the wire bonds 519 and the mounting pad 537. Leads 511 are configured to be coupled to one voltage regime, and leads 510 are electrically isolated from leads 511 and are configured to be coupled to a second voltage regime. The die pad 533 where semiconductor die 505 is mounted is in electrical contact with the semiconductor die 505 and one of the leads 511, and can be coupled to a ground potential. The die pad 531 where semiconductor die 506 is mounted is in contact with the semiconductor die 506 and one of the leads 510, and can be coupled to another ground potential different from the ground potential coupled to semiconductor die 505. The transformer 453 is mounted to the mounting pad 537 with non-conductive die attach film (not visible) and is electrically isolated from the leads. The transformer 453 provides a first coil that can be electrically coupled to semiconductor die 506, and a second coil that can be electrically isolated from the first coil and coupled to semiconductor die 505. In one example application, current can be applied to the first coil, and by inducing a current in the second coil corresponding to the current applied to first coil, energy can be transferred across the isolation barrier formed by the transformer and delivered to the second semiconductor die. The semiconductor device package 500 can be used to package devices to implement a DC-DC converter function, such as the circuit 300 in FIG. 3. Other circuits using transformers can be formed using the transformer of the arrangements, and can be packaged in a semiconductor device package, for example, AC-DC converters, battery chargers, and power supplies can be implemented using the transformer of the arrangements. The laminate transformer of the arrangements with integral magnetic material provides a low-cost assembly for a semiconductor device package with an integral transformer, when compared to prior approaches formed without use of the arrangements.

While the laminate transformer with integral magnetic material 453 can be used in a semiconductor device package, as shown in FIGS. 5C-5H, in additional alternative arrangements, the laminate transformer can be used as a component mounted to a semiconductor device package, as part of a stacked package assembly, or on a module or circuit board to provide a transformer component.

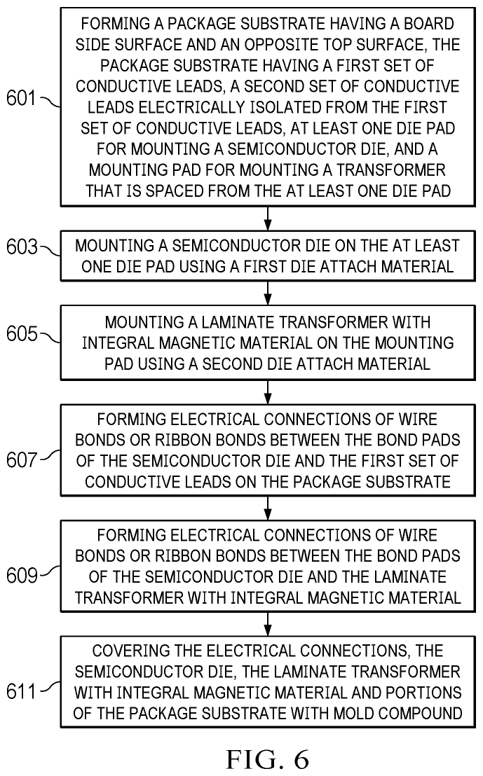

FIG. 6 illustrates, in a flow diagram, selected steps for forming a semiconductor device package of the arrangements.

In FIG. 6, at step 601, the method begins by forming a package substrate having a board side surface and an opposite top surface, the package substrate having a first set of conductive leads, a second set of conductive leads electrically isolated from the first set of conductive leads, at least one die pad for mounting a semiconductor die, and a mounting pad for mounting a transformer that is spaced from the at least one die pad; (see the leadframe 521 in FIG. 5C, for example with die pad 531, mounting pad 535, first set of conductive leads 510, and second set of conductive leads 511).

At step 603, the method continues by mounting a semiconductor die on the at least one die pad using a first die attach material (see, for example, FIG. 5C, with semiconductor die 505 mounted on die pad 533, note the die attach material is not visible as it lies beneath the semiconductor die).

At step 605, the laminate transformer with integral magnetic material is mounted on the mounting pad using a second die attach material. (See, for example, the laminate transformer 453 in FIG. 5D mounted to the mounting pad 535 by die attach material 537.) In the example arrangements, the second die attach material is non-conductive die attach film. In alternative arrangements, non-conductive die attach epoxy or pastes could be used. A thermal cure or other cure, depending on the type of die attach material selected, is performed.

At step 607, electrical connections of wire bonds or bond ribbons are formed between leads on the package substrate and bond pads on the at least one semiconductor die. (See, for example, wire bonds 519 formed between the semiconductor die 505 and leads 511 of the package substrate 521 in FIG. 5E).

At step 609, electrical connections of wire bonds or ribbon bonds are formed between the laminate transformer and the at least one semiconductor die. (See, for example, wire bonds 519 in FIG. 5E between the semiconductor die 505 and the laminate transformer 453). In an example arrangement, the semiconductor die 505 is coupled to one of the coils in the laminate transformer (see circuit 300 in FIG. 3, with transformer 353 having two coils, one coil coupled to a primary side driver 361, for example). Note that the wire bonding steps 607, 609 can be done in any order or can be done in parallel.

At step 611, the method completes by covering the electrical connections, the semiconductor die, the laminate transformer with integral magnetic material and portions of the package substrate with mold compound. (See, for example, FIG. 5F where mold compound 523 is shown, and see FIG. 5H, where leads 510 and 511 of the leadframe are shown partially covered by the mold compound 523). While the method of FIG. 6 illustrates mounting at least one semiconductor die and a transformer to the package substrate, the illustrated examples show two semiconductor dies and a transformer mounted to the package substrate, to increase integration and to provide a complete circuit within the semiconductor device package. Additional alternative arrangements can be formed, for example a third semiconductor die, or additional passive components, including a second laminate transformer, capacitors, resistors, diodes, sensors or inductors can be mounted to the package substrate.

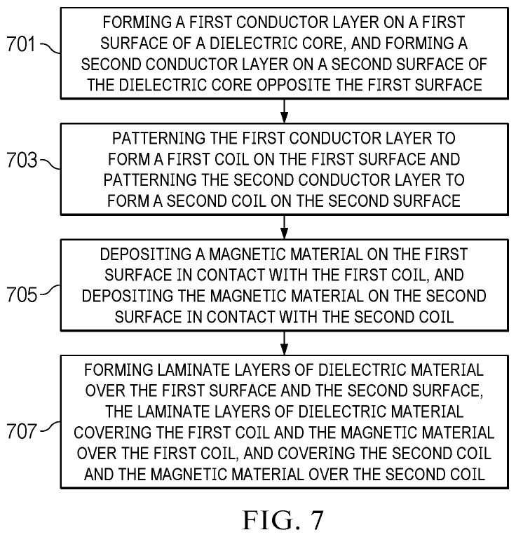

FIG. 7 illustrates in a flow diagram a series of selected steps, a method for making the laminate transformer with integral magnetic material used in the arrangements as described above. The method begins at step 701, by forming a first conductor layer on a first surface of a dielectric core, and forming a second conductor layer on a second surface of the dielectric core opposite the first surface. (See, for example, the core 492 and first conductor layer 491, and second conductor layer 493, in FIG. 4A).

At step 703, the method continues by patterning the first conductor layer to form a first coil on the first surface and patterning the second conductor layer to form a second coil on the second surface. (See, for example, the first coil 495, and the second coil 496, on opposite sides of core 492, in FIG. 4B).

At step 705, the method continues by depositing magnetic material on the first surface in contact with the first coil, and depositing the magnetic material on the second surface in contact with the second coil. (See, for example, magnetic material 482 on the first coil 495 on conductor 492, and magnetic material 484 on the second coil 496 on conductor 492, in FIG. 4C).

At step 707, laminate layers of dielectric material are formed over the first surface and the second surface, the laminate layers of dielectric material covering the first coil and the magnetic material over the first coil, and covering the second coil and the magnetic material over the second coil. (See, for example, laminate layer 486, and laminate layer 488 in FIG. 4D). The laminate layers can be formed by using ABF, or prepreg layers, and conductors can be formed in layers or over the external surfaces to make traces to contact the coils 495, 496 (see FIG. 4E with conductors 487, 488 in the laminate layers).

The laminate transformer with integral magnetic material (see laminate transformer 453 in FIG. 4E) is a passive component that can be used within a semiconductor device package, as shown in FIGS. 5C-5H. In additional alternative arrangements, the laminate transformer can be used as a component mounted to or on a semiconductor device package, as part of a stacked package assembly, or on a module or board to provide a transformer.

While the illustrated examples shown in the figures and described herein show the laminate transformer with integral magnetic material mounted in a leaded semiconductor device package, in additional alternative arrangements, the laminate transformer with integral magnetic material and one or more semiconductor dies can be mounted in a no-lead semiconductor device package, such as a QFN. Dual in-line packages (DIPs), small outline IC packages (SOICs), and wide SOIC packages can be used to form additional arrangements.

Modifications are possible in the described arrangements, and other alternative arrangements are possible within the scope of the claims.

What is claimed is:

1. A method of forming a semiconductor device package, comprising:
forming a package substrate having a board side surface and an opposite top surface, the package substrate having a first set of conductive leads, a second set of conductive leads electrically isolated from the first set of conductive leads, at least one die pad for mounting a semiconductor die, and a mounting pad that is spaced from the at least one die pad;
mounting a semiconductor die on the at least one die pad using a first die attach material;
mounting a laminate transformer with integral magnetic material on the mounting pad using a second die attach material;
forming first electrical connections of wire bonds or ribbon bonds between the bond pads of the semiconductor die and the first set of conductive leads on the package substrate;
forming second electrical connections of wire bonds or ribbon bonds between the bond pads of the semiconductor die and the laminate transformer with integral magnetic material; and
covering the first and second electrical connections, the semiconductor die, the laminate transformer with integral magnetic material and portions of the package substrate with mold compound.

2. The method of claim 1, wherein mounting a semiconductor die on the at least one die pad further comprises mounting the semiconductor die that is a first semiconductor die on the at least one die pad, and mounting a second semiconductor die on a second die pad that is electrically isolated from the at least one die pad.

3. The method of claim 2, wherein forming first electrical connections of wire bonds or ribbon bonds between the bond pads of the semiconductor die and the first set of conductive leads on the package substrate comprises forming the first electrical connections between the bond pads of the first semiconductor die and the first set of leads, and further comprises:
forming third electrical connections of wire bonds or ribbon bonds between bond pads of the second semiconductor die and the second set of leads on the package substrate.

4. The method of claim 3, wherein forming second electrical connections of wire bonds or ribbon bonds between the bond pads of the semiconductor die and the laminate transformer with integral magnetic material comprises forming the second electrical connections between the bond pads of the first semiconductor die and the laminate transformer with integral magnetic material and further comprises forming fourth electrical connections between the bond pads of the second semiconductor die and the laminate transformer with integral magnetic material.

5. The method of claim 4, wherein mounting a laminate transformer with integral magnetic material on the mounting pad using a second die attach material further comprises mounting a laminate transformer that includes:
a first coil on a first surface of a core of dielectric material and a second coil on a second surface of the core opposite the first coil, magnetic material deposited on the first coil on the first surface of the core and deposited on the second coil on the second surface of the core, and laminate layers of dielectric material formed over the magnetic material and the first coil on the first surface of the core, and formed over the magnetic material and the second coil on the second surface of the core.

6. The method of claim 5, wherein the laminate layers of dielectric material are of Ajinomoto build-up film (ABF) or prepreg material.

7. The method of claim 5, wherein the core of dielectric material is of bismaleimide triazine (BT) resin, Ajinomoto build-up film (ABF), or prepreg material.

8. The method of claim 5, wherein forming second electrical connections of wire bonds or ribbon bonds between the bond pads of the semiconductor die and the laminate transformer with integral magnetic material comprises forming the second electrical connections between the bond pads of the first semiconductor die and the first coil and further comprising forming the fourth electrical connections between the bond pads of the second semiconductor die and the second coil of the laminate transformer with integral magnetic material.

9. The method of claim 1, wherein the package substrate is a leadframe with the first set of conductive leads and the second set of conductive leads, and wherein covering the electrical connections, the semiconductor die, the laminate transformer with integral magnetic material and portions of the package substrate with mold compound further comprises covering a portion of the first set of conductive leads and a portion of the second set of conductive leads with mold compound, while another portion of the first set of conductive leads and another portion of the second set of conductive leads remain exposed from the mold compound, forming terminals for a leaded semiconductor device package.

10. The method of claim 1, wherein the first die attach material is a conductive die attach material, and the second die attach material is a non-conductive die attach material.

11. The method of claim 10, wherein the conductive die attach material is a conductive die attach film, and the non-conductive die attach material is a non-conductive die attach film.

12. A method for forming a transformer, comprising:
forming a first conductor layer on a first surface of a dielectric core, and forming a second conductor layer on a second surface of the dielectric core opposite the first surface;
patterning the first conductor layer to form a first coil on the first surface and patterning the second conductor layer to form a second coil on the second surface;
depositing a magnetic material on the first surface in contact with the first coil, and depositing the magnetic material on the second surface in contact with the second coil; and
forming laminate layers of dielectric material over the first surface and the second surface, the laminate layers of dielectric material covering the first coil and the magnetic material over the first coil, and covering the second coil and the magnetic material over the second coil.

13. The method of claim 12, wherein patterning the first conductor layer to form a first coil on the first surface and patterning the second conductor layer to form a second coil on the second surface further comprises patterning the first conductor to form the first coil that is a planar coil and patterning the second conductor to form the second coil that is a planar coil aligned to the first coil, and wherein the first coil, the second coil and the dielectric core form a transformer.

14. The method of claim 12, wherein forming laminate layers of dielectric material over the first surface and the second surface covering the first coil and the magnetic material over the first coil, and covering the second coil and the magnetic material over the second coil, further comprises forming the laminate layers of Ajinomoto build-up film (ABF) or forming the laminate layers of prepreg material.

15. The method of claim 14, and further comprising forming first conductors over the laminate layers, the first conductors coupled to the first coil on the first surface and forming second conductors over the laminate layers coupled to the second coil on the second surface.

16. The method of claim 12, wherein depositing a magnetic material further comprises depositing a magnetic paste or depositing a magnetic ink.

17. A semiconductor device package, comprising:
a package substrate comprising a mounting pad, at least one die pad, a first set of conductive leads, and a second set of conductive leads spaced from the first set of conductive leads;
a semiconductor die mounted to the at least one die pad with a first die attach material;
a laminate transformer with integral magnetic material mounted on the mounting pad with a second die attach material;
first electrical connections of wire bonds or ribbon bonds between the bond pads of the semiconductor die and the first set of conductive leads on the package substrate;
second electrical connections of wire bonds or ribbon bonds between the bond pads of the semiconductor die and the laminate transformer with integral magnetic material; and
mold compound covering the electrical connections, the semiconductor die, the laminate transformer with integral magnetic material and portions of the package substrate.

18. The semiconductor device package of claim 17, wherein the magnetic material is a magnetic paste or a magnetic ink deposited in contact with the first coil and the second coil.

19. The semiconductor device package of claim 17, wherein the at least one die pad of the package substrate is a first die pad, and the semiconductor die mounted on the at least one die pad is a first semiconductor die, and further comprising a second die pad on the leadframe electrically isolated from the first die pad, and further comprising a second semiconductor die mounted to the second die pad by the first die attach material.

20. The semiconductor device package of claim 19, wherein the first semiconductor die, the second semiconductor die, and the laminate transformer are coupled to implement DC-DC converter function.

21. A transformer, comprising:
a first coil formed in a first conductor layer on a first surface of a dielectric core, and a second coil formed in a second conductor layer on a second surface of the dielectric core opposite the first surface;
a magnetic material on the first surface in contact with the first coil, and the magnetic material on the second surface in contact with the second coil; and
laminate layers of dielectric material over the first surface and the second surface, the laminate layers of dielectric material covering the first coil and the magnetic material over the first coil, and covering the second coil and the magnetic material over the second coil.

22. The transformer of claim 21, wherein the magnetic material comprises magnetic material formed from magnetic paste deposited over the first surface and the second surface.

23. The transformer of claim 21, wherein the magnetic material comprises magnetic material formed from magnetic ink deposited over the first surface and the second surface.

24. The transformer of claim 21, wherein the laminate layers are of Ajinomoto build-up film (ABF) or prepreg material.
